(19) United States
(12) Patent Application Publication
(10) Pub. No.: US 2003/0122178 A1
(43) Pub. Date: Jul. 3, 2003

(54) Method for fabricating a flash memory having a T-shaped floating gate

(75) Inventor: Hsiao-Ying Yang, Hsinchu (TW)

Correspondence Address: BRUCE H. TROXELL, 5205 LEESBURG PIKE, SUITE 1404, FALLS CHURCH, VA, 22041, US

(73) Assignee: VANGUARD INTERNATIONAL SEMICONDUCTOR CORPORATION

(21) Appl. No.: 10/159,015

(22) Filed: Jun. 3, 2002

(30) Foreign Application Priority Data
Dec. 21, 2001 (TW) 90131774

(51) Int. Cl. H01L 21/336; H01L 21/8234; H01L 29/76

(52) U.S. Cl. 257/314; 438/197

(57) ABSTRACT

The present invention discloses a method for fabricating a flash memory having a T-shaped floating gate, comprising the steps of: forming a coupling oxide layer, a buffered layer, and a sacrificial layer in sequence on a semiconductor substrate; forming shallow trench isolation (STI); removing the portion of STI and said sacrificial layer so as to form a flat surface; forming a conductive layer; patterning said conductive layer so that a T-shaped floating gate is formed from the conductive layer and the buffered layer. The buffered layer and said conductive layer are made of a material selected from the group consisting of polysilicon, suicide and amorphous silicon wherein the buffered layer is formed to be 200 to 2500 Å in thickness is and the conductive layer is formed to be 300 to 3000 Å in thickness.

### BACKGROUND OF THE INVENTION

1. Field of the Invention

The present invention generally relates to a method for fabricating a flash memory having a T-shaped floating gate, and more particularly, to a method for producing T-shaped floating gate having high capacitive coupling ratio.

2. Description of the Prior Art

A flash memory has two modes of operations: electrical program and electrical erasure. In general, the basic configuration of flash memory is composed of two major portions: the memory cell array and the peripheral circuit, and the flash memory cell array for data storage is constructed by a plurality of memory cells regularly arranged in an array based on the intersected word lines and bit lines. The peripheral circuit provides the flash memory with functions such as power supply and data processing during operation. Flash memories can be classified according to the gate electrode structures, one is stack-gate memory cell, and the other is split-gate memory cell.

In the prior art, please refer to FIGS. 1A to 1D, in which the method for fabricating high-density stack-gate flash memory is schematically illustrated. As shown in FIG. 1A, a semiconductor substrate 1 is provided, on which a coupling oxide layer 2, a buffered layer 3, and a silicon nitride layer 4 are formed in sequence and the shallow trench isolation 5(STI) is also formed. As shown in FIG. 1B, the portion of shallow trench isolation 5 is removed, and then the coupling oxide layer 2 and the buffered layer 3 are removed in sequence. After that, a polysilicon layer 6 is deposited for conducting, and patterned by standard photolithography process to be as a floating gate 6a, as shown in FIGS. 1C and 1D.

Obviously, in the prior art, after the buffered layer 3 is removed, the polysilicon layer 6 is deposited and patterned to be as a floating gate 6a, so that it would increase the complexity and decrease the reliability of the process. Moreover, it cannot increase the capacitive coupling ratio to improve the electric property of the flash memory.

### SUMMARY OF THE INVENTION

It is the primary object of the present invention to provide a method for fabricating a flash memory having a T-shaped floating gate so as to fabricate a flash memory having high capacitive coupling ratio.

It is another object of the present invention to provide a method for fabricating a flash memory having a T-shaped floating gate so as to decrease the complexity of process.

It is another object of the present invention to provide a method for fabricating a flash memory having a T-shaped floating gate so as to increase the reliability of process and yield.

In order to achieve the foregoing object, the present invention provides a method for fabricating a flash memory having a T-shaped floating gate, comprising the steps of:

forming a coupling oxide layer, a buffered layer, and a sacrificial layer in sequence on a semiconductor substrate;

forming shallow trench isolation (STI); removing the portion of STI and said sacrificial layer so as to form a flat surface;

forming a conductive layer; patterning said conductive layer so that a T-shaped floating gate is formed from the conductive layer and the buffered layer.

In preferred embodiment of this invention, the buffered layer and said conductive layer are made of a material selected from the group consisting of polysilicon, silicide and amorphous silicon wherein the buffered layer is formed to be 200 to 2500 Å in thickness and the conductive layer is formed to be 300 to 3000 Å in thickness.

### BRIEF DESCRIPTION OF THE DRAWINGS

The objects, spirits and advantages of the preferred embodiment of the present invention will be readily understood with reference to the accompanying drawings and detailed descriptions, wherein:

FIGS. 1A to 1D schematically illustrates a method for fabricating flash memory gate in accordance with the prior art.

FIGS. 2A to 2E schematically illustrates a method for fabricating a flash memory having a T-shaped floating gate in accordance with the embodiment of the present invention.

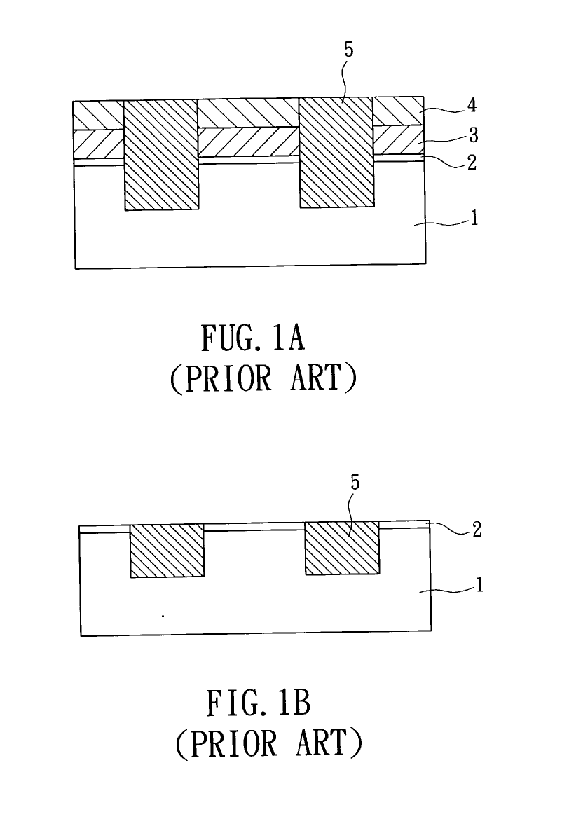

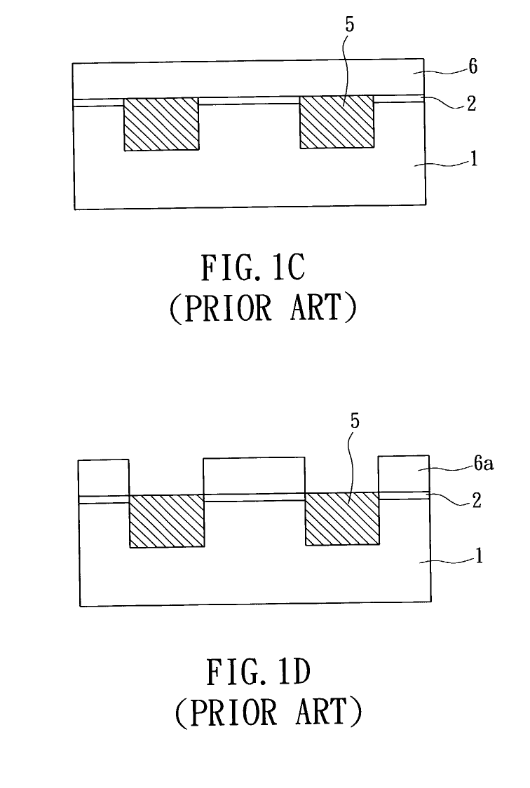

### DETAILED DESCRIPTION OF THE INVENTION

The present invention provides a method for fabricating a flash memory having a T-shaped floating gate, comprising the steps of:

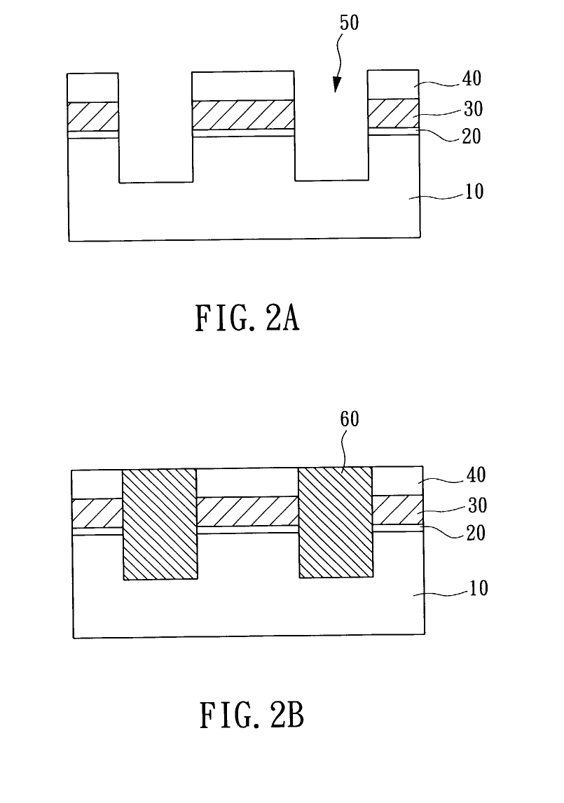

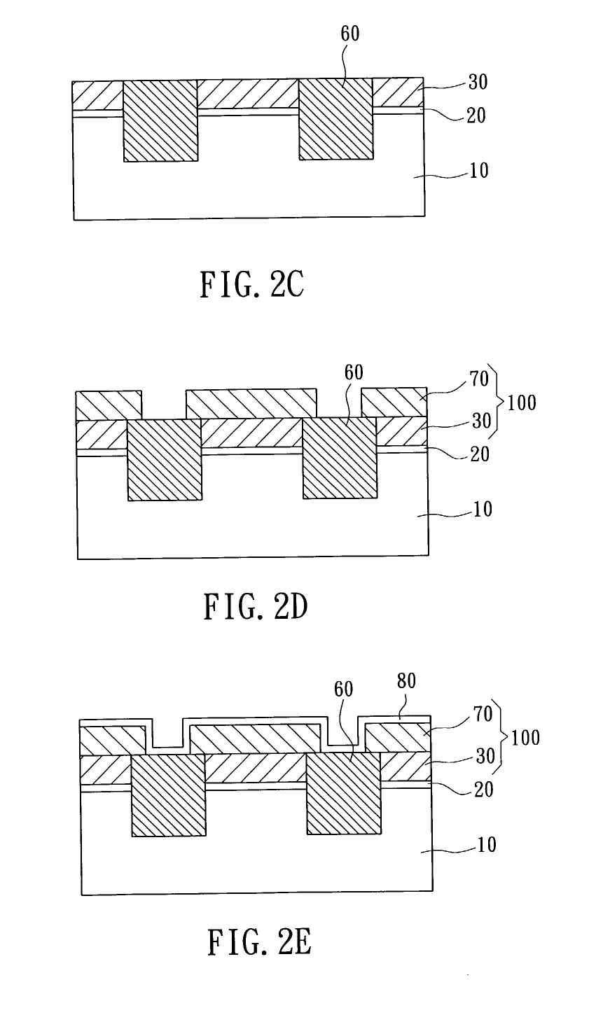

(a) forming a coupling oxide layer 20, a buffered layer 30, and a sacrificial layer 40 in sequence on a semiconductor substrate 10; spin coating a photoresist on the sacrificial layer 40, defining a shallow trench isolation area 50 by exposing and developing with a mask, and then etching the coupling oxide layer 20, the buffered layer 30, and the sacrificial layer 40 which are not covered by the photoresist; etching the semiconductor substrate 10 by reactive ion etch (RIE) to form the shallow trench isolation area 50, as shown in FIG. 2A. In general, the components of the ion beam of RIE are SF₆ and Cl₂ mixed gas. The buffered layer 30 with a width of about 200 to 2500 Å is made of a material selected from the group consisting of polysilicon, silicide, amorphous silicon and the like.

(b) forming SiO₂ to fill the shallow trench isolation area 50 by Sub-Atmospherical Chemical Vapor Deposition (SACVD) or High Density Plasma Chemical Vapor Deposition (HDPCVD), and then forming a shallow trench isolation 60 (STI) by Chemical Mechanical Polishing (CMP) for planarization, in order to isolate each active area, as shown in FIG. 2B. The sacrificial layer 40 is as an etching stop layer in the CMP process, and is made of a material selected from the group consisting of silicon nitride and the like.

(c) removing the portion of shallow trench isolation 60 by buffer oxide etch (BOE) and then removing the sacrificial layer 40 so as to form a flat surface, as shown in FIG. 2C.

(d) depositing a conductive layer 70 and patterning the conductive layer 70 so that a T-shaped floating-gate 100 is formed from the conductive layer 70 and the buffered layer 30. Because the edge of conductive layer 70 is more than the buffered layer 30, it will increase the capacitive coupling ratio of the stack-gate so as to increase the electrical property of flash memory, as shown in FIG. 2D. The conductive layer 70 with a width of about 300 to 3000 Å is made of a material selected from the group consisting of polysilicon, suicide, amorphous silicon and the like.

(e) depositing a thin dielectric layer 80 as an intermediate layer between T-shaped floating-gate 100 and control gate, as shown in FIG. 2E. The thin dielectric layer 80 with a width of about 50 to 300 Å is made of a material selected from nitride-oxide (NO), oxide-nitride-oxide (ONO) and the like.

As described above, the present invention provides a method for fabricating a flash memory having a T-shaped floating gate, wherein said flash memory having a T-shaped floating gate comprising: a coupling oxide layer 20, a buffered layer 30 and a conductive layer 70 on a semiconductor substrate 10 in sequence, which are separated by shallow trench isolation 60 (STI). The improvement of this invention is: a floating-gate 100, T-shaped, formed from the buffered layer 30 and the conductive layer 70 on the buffered layer 30.

In conclusion, the present invention has at least the following advantages:

(a) the buffered layer needn't to be removed in this method, which is less complex than the process of prior art having the step of removing the buffered layer and then depositing conductive layer, so that it can increase the reliability of process.

(b) According to the structure of T-shaped floating gate in this present invention, the edge of conductive layer is more than the buffered layer, so it will increase the capacitive coupling ratio of stack-gate so as to increase the electrical property of the flash memory.

The present invention has been examined to be progressive and has great potential in commercial applications.

Although this invention has been disclosed and illustrated with reference to particular embodiments, the principles involved are susceptible for use in numerous other embodiments that will be apparent to persons skilled in the art. This invention is, therefore, to be limited only as indicated by the scope of the appended claims.

What is claimed is:

1. Method for fabricating a flash memory having a T-shaped floating gate, comprising the steps of:
(a) forming a coupling oxide layer, a buffered layer, and a sacrificial layer in sequence on a semiconductor substrate;
(b) forming shallow trench isolation (STI);
(c) removing the portion of STI and said sacrificial layer so as to form a flat surface;
(d) forming a conductive layer;
(e) patterning said conductive layer so that a T-shaped floating gate is formed from the conductive layer and the buffered layer.

2. The method for fabricating a flash memory having a T-shaped floating gate as recited in claim 1, further comprising a step (f) after step (e):
(f) forming a thin dielectric layer.

3. The method for fabricating a flash memory having a T-shaped floating gate as recited in claim 1, wherein said buffered layer and said conductive layer are made of a material selected from the group consisting of polysilicon, silicide and amorphous silicon.

4. The method for fabricating a flash memory having a T-shaped floating gate as recited in claim 1, wherein said sacrificial layer is silicon nitride.

5. The method for fabricating a flash memory having a T-shaped floating gate as recited in claim 1, wherein said buffered layer is formed to be 200 to 2500 Å in thickness.

6. The method for fabricating a flash memory having a T-shaped floating gate as recited in claim 1, wherein said conductive layer is formed to be 300 to 3000 Å in thickness.

7. The method for fabricating a flash memory having a T-shaped floating gate as recited in claim 2, wherein said thin dielectric layer is made of a material selected from the group consisting of nitride-oxide (NO) and oxide-nitride-oxide (ONO).

8. The method for fabricating a flash memory having a T-shaped floating gate as recited in claim 2, wherein said thin dielectric layer is formed to be 50 to 300 Å in thickness.

9. A structure of a flash memory having a T-shaped floating gate, comprising: a coupling oxide layer, a buffered layer and a conductive layer on a semiconductor substrate in sequence separated by shallow trench isolation (STI),
the improvement being as:
a floating-gate, T-shaped, formed from the buffered layer and the conductive layer on the buffered layer.

10. The structure of a flash memory having a T-shaped floating gate as recited in claim 9, wherein said buffered layer and said conductive layer are made of a material selected from the group consisting of polysilicon, suicide and amorphous silicon.

11. The structure of a flash memory having a T-shaped floating gate as recited in claim 9, wherein said buffered layer is formed to be 200 to 2500 Å in thickness.

12. The structure of a flash memory having a T-shaped floating gate as recited in claim 9, wherein said conductive layer is formed to be 300 to 3000 Å in thickness.
